(19) United States
(12) Patent Application Publication
(10) Pub. No.: US 2025/0301732 A1
(43) Pub. Date: Sep. 25, 2025

(54) Power Semiconductor Device and Method of Producing a Power Semiconductor Device

(71) Applicant: Infineon Technologies AG, Neubiberg (DE)

(72) Inventor: Hans-Jürgen Thees, Dresden (DE)

(21) Appl. No.: 19/083,533

(22) Filed: Mar. 19, 2025

(30) Foreign Application Priority Data
Mar. 20, 2024 (DE) 102024202658.1

(51) Int. Cl. H10D 62/10; H10D 12/00; H10D 12/01; H10D 30/01; H10D 30/66

(52) U.S. Cl. CPC H10D 62/127; H10D 12/038; H10D 12/481; H10D 30/0297; H10D 30/665; H10D 30/668

(57) ABSTRACT

A power semiconductor device includes: a trench structure having one or more control trenches each including a control trench electrode isolated from the first load terminal and configured to control a forward load current; and a plurality of source trenches each including a source trench electrode electrically connected to the first load terminal. A plurality of mesas is configured to conduct the forward load current, each mesa surrounding one of the source trenches and being surrounded by one or more of the one or more control trenches. A plurality of first contact plugs extends along the vertical direction from the first load terminal towards the first side. Each first contact plug is associated with one of the source trenches and one of the mesas surrounding the source trench, and is configured to contact both the mesa and the source trench electrode of the source trench.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

In a typical IGBT design, said gate electrodes are accommodated in a trench structure that extends into the semiconductor body. The trench structure spatially confines portions of the semiconductor body, typically referred to as mesas, in which conductive channels may be formed that allow flow of the forward load current. The conductive channels, typically based on a semiconductor source region and a semiconductor body region of opposite conductivity type as the source region, are controlled based on the adjacent control electrodes.

For example, to reach a favorable charge carrier confinement, a certain dimension of the mesas may be appropriate, e.g., in terms of lateral extension (width) and/or vertical extension (height). However, if the width of the mesa becomes smaller, it may become more challenging to reliably establish an electrical connection between the mesa and the load terminal.

### SUMMARY

According to an embodiment, a power semiconductor device comprises an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; in the active region, a trench structure extending along a vertical direction from the first side towards the second side, wherein the trench structure comprises one or more control trenches, each of the one or more control trenches including a control trench electrode isolated from the first load terminal and configured to control the forward load current, and a plurality of source trenches, each source trench including a source trench electrode electrically connected to the first load terminal; in the active region, a plurality of mesas configured for conducting the forward load current and extending along the vertical direction from the first side towards the second side, wherein each mesa surrounds a respective one of the source trenches and is surrounded by one or more of the one or more control trenches; and in the active region, a plurality of first contact plugs extending along the vertical direction from the first load terminal towards the first side, wherein each first contact plug is associated with one of the source trenches and one of the mesas surrounding said source trench and is configured to contact both said mesa and the source trench electrode of said source trench.

According to another embodiment, a method of producing a power semiconductor device comprises forming the following components: an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; in the active region, a trench structure extending along a vertical direction from the first side towards the second side, wherein the trench structure comprises one or more control trenches, each of the one or more control trenches including a control trench electrode isolated from the first load terminal and configured to control the forward load current, and a plurality of source trenches, each source trench including a source trench electrode electrically connected to the first load terminal; in the active region, a plurality of mesas configured for conducting the forward load current and extending along the vertical direction from the first side towards the second side, wherein each mesa surrounds a respective one of the source trenches and is surrounded by one or more of the one or more control trenches; and in the active region, a plurality of first contact plugs extending along the vertical direction from the first load terminal towards the first side, wherein each first contact plug is associated with one of the source trenches and one of the mesas surrounding said source trench and is configured to contact both said mesa and the source trench electrode of said source trench.

In accordance with embodiments described herein, both the electrical connections to the control trench electrodes and the source trench electrodes may be established based on the same etch processing step, as will be explained in more detail below. Furthermore, each of the first contact plugs may simultaneously contact both one of the mesas and its associated source trench electrode. Also, as the mesas may exhibit a respective chimney-like shape, the first contact plugs that connect the mesas with the first load terminal may be realized as self-aligned contact plugs. Furthermore, mesas exhibiting a comparatively small width may be achieved.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a vertical cross-section of a power semiconductor device in accordance with one or more embodiments;

FIG. 3(A) schematically and exemplarily illustrates a vertical cross-section of a power semiconductor device in accordance with one or more embodiments;

FIG. 3(B) schematically and exemplarily illustrates a section of a perspective view of a mesa of a power semiconductor device in accordance with one or more embodiments;

FIG. 3(C) schematically and exemplarily illustrates a section of an exploded view of a mesa and a first contact plug of a power semiconductor device in accordance with one or more embodiments;

FIGS. 4(A)-(C) each schematically and exemplarily illustrate a section of an exploded view of a mesa and a first contact plug of a power semiconductor device in accordance with one or more embodiments;

FIG. 5 schematically and exemplarily illustrates a horizontal projection of a section of an active region of a power semiconductor device in accordance with one or more embodiments; and

FIGS. 6-19 schematically and exemplarily illustrate, based on several vertical cross-sections and horizontal projections, a method of producing a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

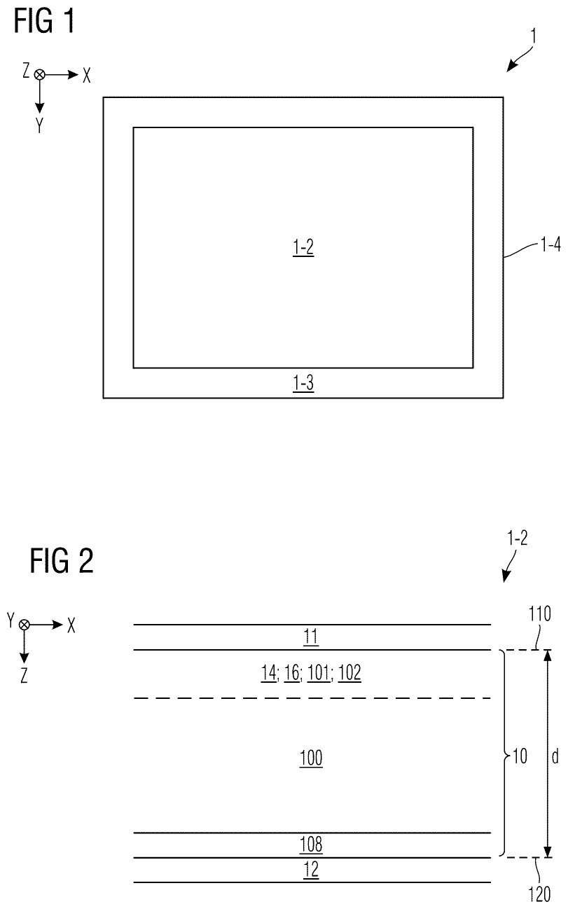

With respect to FIGS. 1 and 2, aspects related to a possible general configuration of a power semiconductor device 1 shall be explained.

The power semiconductor device 1, herein also referred to as “device 1”, comprises, e.g., in a single chip, a semiconductor body 10 configured to conduct a load current, in an active region 1-2, between a first load terminal 11 at a first side 110 of the semiconductor body 10 and a second load terminal 12 at a second side 120 of the semiconductor body 10. The device 1 can be, e.g., an IGBT (or a derivative thereof, such as RC IGBT) or, e.g., a MOSFET (or a derivative thereof). Accordingly, the first load terminal 11 may be an emitter terminal (or source terminal), and the second load terminal 12 may be a drain terminal.

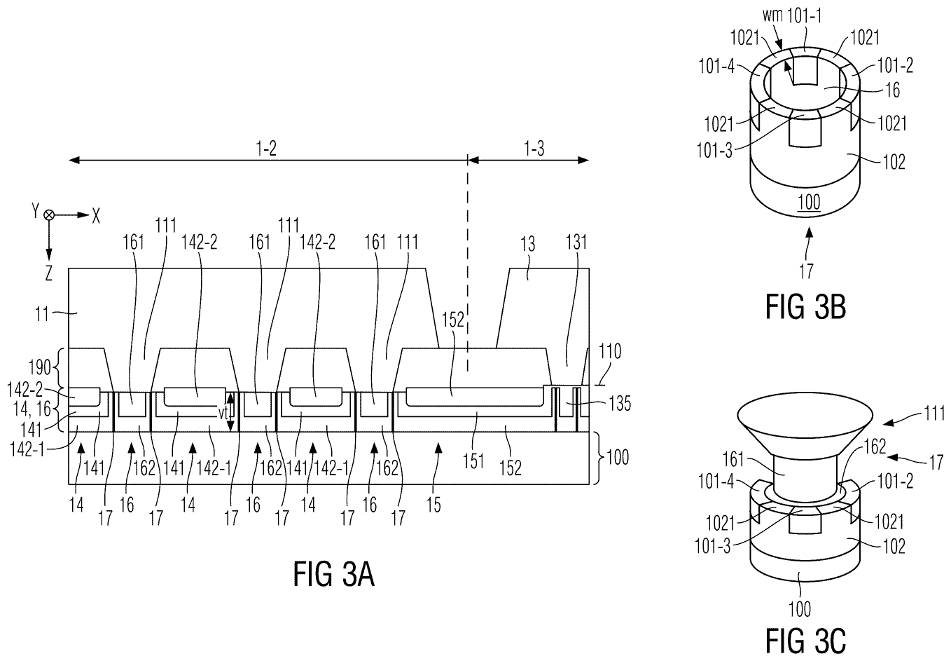

As exemplarily illustrated in FIG. 1, the active region 1-2 of the device 1 is surrounded by an edge termination region 1-3. In the active region 1-2, a trench structure (cf. FIG. 3, reference numerals 14, 16) may form a cell field, which will be explained further below. The edge termination region 1-3 is typically not employed for load current conduction, as it is known to the skilled person. The edge termination region 1-3 is terminated by the chip edge 1-4.

As exemplarily illustrated in FIG. 2, the first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 40 μm to 750 μm, depending, e.g., on the designated maximal blocking voltage.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., the maximal blocking voltage) of the device 1.

The device 1 further comprises a trench structure 14, 16 that extends from the first side 110 into the semiconductor body 10 towards the second side 120, e.g., along the vertical direction Z. The trench structure will be described in greater detail below. The trench structure 14, 16 comprises control trench electrodes 141 (cf. FIG. 3(A)) electrically insulated from the first load terminal 11 and configured to receive a control signal. To this end, the control trench electrodes 141 can be electrically connected to a control terminal 13 of the device 1, in accordance with an embodiment.

As illustrated schematically in FIG. 2 and in more detail in FIGS. 3(B) and 3(C), at the first side 110, the semiconductor body 10 further comprises a semiconductor body region 102 of the second conductivity type electrically connected to the first load terminal 11 and a semiconductor source region 101 of the first conductivity type electrically connected to the first load terminal 11, wherein the semiconductor source region 101 is isolated from the drift region 100 by at least the semiconductor body region 102. The control trench electrode 141 of the trench structure can be configured to induce, upon being subjected with a corresponding ON-control signal, an inversion channel in the semiconductor body region 102. This process may set the device 1 into the conducting state. The control trench electrode 141 can further be configured to cut off, upon being subjected with a corresponding OFF-control signal, said inversion channel in the semiconductor body region 102, which can set the device 1 into the forward biased blocking state.

Referring to FIG. 2 again, a doped region 108 of the semiconductor body 10 below the drift region 100 adjoining the second load terminal 12 at the second side 120 can be configured in accordance with the designated characteristic of the device 1.

For example, the doped region 108 can be an emitter region of the second conductivity type, if the device 1 shall exhibit an IGBT configuration. The doped region 108 is arranged in contact with the second load terminal 12. If the device 1 shall exhibit an RC IGBT configuration, the doped region 108 can be an emitter region of the second conductivity type exhibiting subsections of the first conductivity type, as it is known to the skilled person.

If the device 1 shall exhibit a MOSFET configuration, the doped region 108 can be a highly doped region of the first conductivity type adjoining the second load terminal 12.

In addition, a field stop region (not illustrated) of the first conductivity type can be provided between the drift region 100 and the second load terminal 12, wherein the field stop region exhibits a greater dopant concentration than the drift region 100.

FIGS. 3(A)-3(C) schematically and exemplarily illustrate an embodiment of the power semiconductor device 1.

In this embodiment, the trench structure, cf. FIG. 3(A), comprises several control trenches 14, wherein each of the control trenches 14 includes a control trench electrode 141 isolated from the first load terminal 11 and configured to control the forward load current. Further, the trench structure comprises, in this embodiment, a plurality of source trenches 16, wherein each of the source trenches 16 includes a source trench electrode 161 electrically connected to the first load terminal 11.

Still referring to the embodiment illustrated in FIGS. 3(A)-3(C), the device 1 further comprises, in the active region 1-2, a plurality of mesas 17 configured for conducting the forward load current and extending along the vertical direction Z from the first side 110 towards the second side 120.

Each mesa 17 surrounds a respective one of the source trenches 16. For example, each mesa completely surrounds a respective one of the source trenches 16. In an embodiment, each of the source trenches 16 is surrounded, e.g., completely, by a respective one of the mesas 17.

Furthermore, each mesa 17 is surrounded, e.g., completely (cf. also FIG. 5) by one or more of the one or more control trenches 14, in accordance with an embodiment.

The control trenches 14 and the source trenches 16 may accordingly laterally confine said mesas 17. For example, wherein the trench structure exhibits a pattern, in the active region 1-2, according to which each source trench 16 is surrounded by one or more of the control trenches 14 (cf. also FIG. 5).

The device 1 furthermore comprises, in the active region 1-2, a plurality of first contact plugs 111 extending along the vertical direction Z from the first load terminal 11 towards the first side 110. Each first contact plug 111 is associated with one of the source trenches 16 and one of the mesas 17 surrounding said source trench 16. For example, the first contact plugs 111 penetrate an insulation layer 190 arranged between the semiconductor body 10 and the first load terminal 11. Each first contact plug 111 is configured to contact both said mesa 17 and the source trench electrode 161.

In an embodiment, each mesa 17 comprises (cf., e.g., FIGS. 3(A) and 3(B)) said semiconductor source region 101 of the first conductivity type and electrically connected to the first load terminal 11 via the associated first contact plug 111. In an embodiment, each mesa 17 further comprises said semiconductor body region 102 of the second conductivity type in contact with the semiconductor source region 101. For example, the semiconductor body region 102 isolates the semiconductor source region 101 from semiconductor the drift region 100.

In an embodiment, in each of the mesas 17, the semiconductor source region 101 exhibits an even number of spatially distributed semiconductor source subregions, e.g., four semiconductor source subregions 101-1, 101-2, 101-3 and 101-4, as illustrated in FIGS. 3(A) and 3(B). The even number of spatially distributed semiconductor source subregions may differ from four; e.g., two, or six or eight spatially distributed semiconductor source subregions are provided. For example, in each of the mesas 17, the semiconductor source region 101 consists of said even number of spatially distributed semiconductor source subregions.

The semiconductor source subregions may be evenly spatially distributed with the respective mesa 17, as illustrated in FIGS. 3(A) and 3(B), where the four semiconductor source subregions 101-1, 101-2, 101-3 and 101-4 are arranged with a respective angular distance of 90° within the mesa 17, which in this embodiment may exhibit an at least approximately circular shape.

For example, as exemplarily illustrated in FIGS. 3(A) and 3(B), in each of the mesas 17, also the semiconductor body region 102 of the second conductivity type is electrically connected to the first load terminal 11 via the associated first contact plug 111. In each of the mesas 17, the semiconductor body region 102 may be arranged at least partially below the semiconductor source region 101. In each of the mesas 17, the semiconductor body region 102 may further comprise portions 1021 that extend between the spatially distributed semiconductor source subregions 101-1 to 101-4 to electrically contact the associated first contact plug 111. Said portions 1021 of the semiconductor body region 102 may accordingly vertically overlap with semiconductor source subregions 101-1 to 101-4. For example, said portions 1021 of the semiconductor body region 102 and the semiconductor source subregions 101-1 to 101-4 are arranged alternately with respect to each other. Said portions 1021 of the semiconductor body region 102 may exhibit a dopant concentration greater than the dopant concentration of the remaining part of the semiconductor body region 102, e.g., at least greater than twice thereof, or even in the range of 100 times the dopant concentration of the remaining part of the semiconductor body region 102.

In an embodiment, the device 1 further comprises, at the first side 110, said control terminal 13 electrically connected with the control trench electrodes 141 of the control trenches 14. For example, a contact between the control terminal 13 and the control trench electrodes 141 is established only in the edge termination region 1-3, e.g., based on a second contact plug 131, as illustrated in FIG. 3(A).

For example, the device 1 further comprises a connector trench 15 extending into the edge termination region 1-3 and the active region 1-2. The connector trench 15 comprises a connector trench electrode 151. The connector trench electrode 151 is arranged, in the edge termination region 1-3, in contact with the second contact plug 131 electrically connected to the control terminal 13. The connector trench electrode 151 extends towards an adjacent one of the mesas 17 in the active region 1-2. The connector trench electrode 151 may be isolated by a connector trench insulator structure 152.

As explained above, upon being subjected with a correspondingly configured control signal, e.g., based on a first control voltage applied between the first load terminal 11 and the control terminal 13, the control electrode 141 adjacent to the mesa 17 may induce an inversion channel in the body region 102 and thereby set the device 1 into the forward conducting state. Upon being subjected with a correspondingly configured other control signal, e.g., based on a second control voltage applied between the first load terminal 11 and the control terminal 13, the control electrode 141 adjacent to the mesa 17 may cut-off the inversion channel in the body region 102 and thereby set the device 1 into the forward biased blocking state.

In an embodiment, each mesa 17 has a width wm (cf. FIG. 3B and FIG. 5 and FIG. 11) within the range of 50 nm to 500 nm, or within a range of 10 nm to 50 nm, or within a range of 50 nm to 100 nm, or within a range of 100 nm to 200 nm. For example, the width of the mesa 17 is defined as the lateral distance between (a) the outer circumference of the source trench 16 that is surrounded by the mesa 17 and (b) the outer circumference of the control trench 14 that surrounds the mesa 17.

In an embodiment, each of the control trenches 14 and each of the source trenches 16 has a vertical extension vt within the range of 0.5 μm to 3 μm, or within a range of 0.5 μm to 1 μm, or within a range of 1 μm to 2 μm, or within a range of 2 μm to 3 μm. The vertical extension vt of the control trenches 14 may be identical to the vertical extension vt of the source trenches or differ therefrom. In an embodiment, the vertical extensions vt of the control trenches 14 and of the source trenches 16 define the vertical extensions of the mesas 17; e.g., the vertical extensions of the mesas 17 are at least approximately identical to the vertical extensions vt of the control trenches 14 and of the source trenches 16.

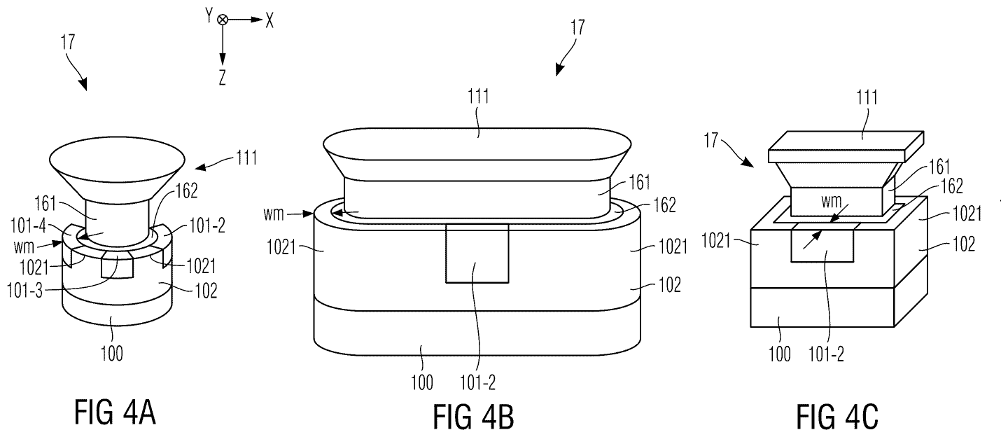

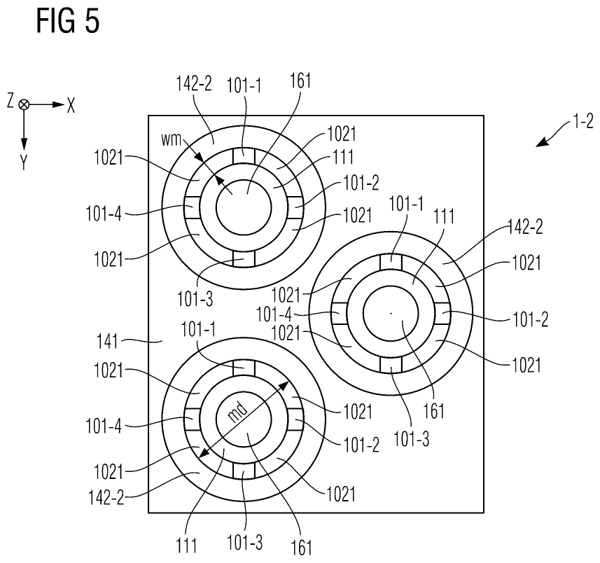

In an embodiment, each of the source trenches 16 has a lateral cross-sectional area smaller than the lateral cross-sectional area of the associated first contact plug 111, as exemplarily illustrated in FIG. 3(A), FIG. 3(C) and FIGS. 4(A)-4(C). For example, the lateral cross-sectional area of each of the first contact plugs 111 decreases along the vertical direction Z by at least 10% or at least 20% of a maximal lateral cross-sectional area of the respective first contact plug 111. In an embodiment, each first contact plug 111 exhibits a corresponding shape of a portion of a cone.

For example, the following applies for each of the source trenches 16: The associated first contact plug 111 laterally overlaps with both the entire source trench 16 and at least partially (or entirely) with the mesa 17 surrounding the source trench 16. For example, at the mesa contact interface, the associated first contact plug 111 laterally overlaps partially with the mesa 17. As the associated first contact plug 111 may extend in lateral cross-section against the vertical direction Z, the associated first contact plug 111 may, at the first load terminal contact interface, laterally overlap entirely with the mesa 17.

In an embodiment, each of the first contact plugs 111 exhibits a monolithic structure. However, one or more non-illustrated intermediate layers, e.g., barrier layers, can be provided between the respective first contact plug 111 and the associated source trench electrode 161 and/or between the respective first contact plug 111 and the associated semiconductor source region 101 and/or between the respective first contact plug 111 and the associated semiconductor body region 102 and/or between the respective first contact plug 111 and the first load terminal 11.

Referring to FIGS. 4(A)-4(C), each of the mesas 17 may exhibit a circular lateral cross-sectional area (cf. FIG. 4(A) and FIGS. 3(A)-3(C)), or a rectangular lateral cross-sectional area with rounded corners (cf. FIG. 4(B)) or a rectangular lateral cross-sectional area (cf. FIG. 4(C)). Irrespective of the shape of the lateral cross-sectional area, the above explained features, e.g., related to mesa width wm, the vertical extensions, the source region 101, the body region 102, the trench structure etc. may likewise be provided. Also, the shape of the source trenches 16 may correspondingly vary, as illustrated in FIGS. 4(A)-4(C).

As exemplarily illustrated in FIG. 5, in accordance with an embodiment, in the active region 1-2, the control trench electrodes 141 of the control trenches 14 may form a monolithic electrode structure. As explained with respect to FIG. 3A, this monolithic electrode structure can be electrically connected to the control terminal 13 based on the connector trench 15, e.g., as exemplarily illustrated in FIG. 3A. For example, the active region 1-2 is devoid of any electrically conducting structure above the first side 110 that is electrically connected to one or more of the control trench electrodes 141.

For example, the active region 1-2 has a total lateral cross-sectional area A. Based on the trench-mesa-pattern explained above, a cell density, i.e., number of separate mesas 17 within the total lateral cross-sectional area A, can amount to, e.g., 1 million cells/mm², or more than 1 million cells/mm². If implemented with a circular lateral cross-sectional shape, each mesa may exhibit a diameter md within a range of 0.4 μm to 1 μm, or within a range of 1 μm to 2 μm.

Additionally referring to FIG. 3(A) again, furthermore, each of the control trenches 14 may comprise a control trench insulator structure with a lower part 142-1 and an upper part 142-2, wherein the lower part 142-1 insulates the respective control trench electrode 141 from the semiconductor body 10. For example, the lower part 142-1 of the control trench insulator structure exhibits, at a bottom of the respective control trench 14, a thickness along the vertical direction Z greater than 150% of a thickness along the first lateral direction X of the control trench insulator 142-1 laterally adjacent to the mesa 17.

Likewise, each of the source trenches 16 may comprise a source trench insulator 162 insulating the respective source trench electrode 161 from the semiconductor body 10. For example, the source trench insulator 162 exhibits, at a bottom of the respective source trench 16, a thickness along the vertical direction Z greater than 150% of a thickness along the first lateral direction X of the source trench insulator 162 laterally adjacent to the mesa 17.

Irrespective of the optional features of the trench insulator thicknesses, each of the control trench electrodes 141 exhibits, in a vertical cross-section, a U-shape, as exemplarily illustrated in FIG. 3(A). For example, the well region of the U-shape is filled with said upper part 142-2 of the control trench insulator structure.

Presented herein is also a method of producing a power semiconductor device. For example, the method of producing a power semiconductor device comprises forming the following components: an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; in the active region, a trench structure extending along a vertical direction from the first side towards the second side, wherein the trench structure comprises one or more control trenches, each of the one or more control trenches including a control trench electrode isolated from the first load terminal and configured to control the forward load current, and a plurality of source trenches, each source trench including a source trench electrode electrically connected to the first load terminal; in the active region, a plurality of mesas configured for conducting the forward load current and extending along the vertical direction from the first side towards the second side, wherein each mesa surrounds a respective one of the source trenches and is surrounded by one or more of the one or more control trenches; and in the active region, a plurality of first contact plugs extending along the vertical direction from the first load terminal towards the first side, wherein each first contact plug is associated with one of the source trenches and one of the mesas surrounding said source trench and is configured to contact both said mesa and the source trench electrode of said source trench.

Embodiments of the above-described method correspond to the embodiments of the power semiconductor device 1 described above. Accordingly, these embodiments of the method will not literally be described herein, but it is referred to the above.

For example, the control trench electrodes and the source trench electrodes are electrically contacted based on a joint etch processing step. Further, forming the first contact plugs may occur such that the first contact plugs are self-aligned.

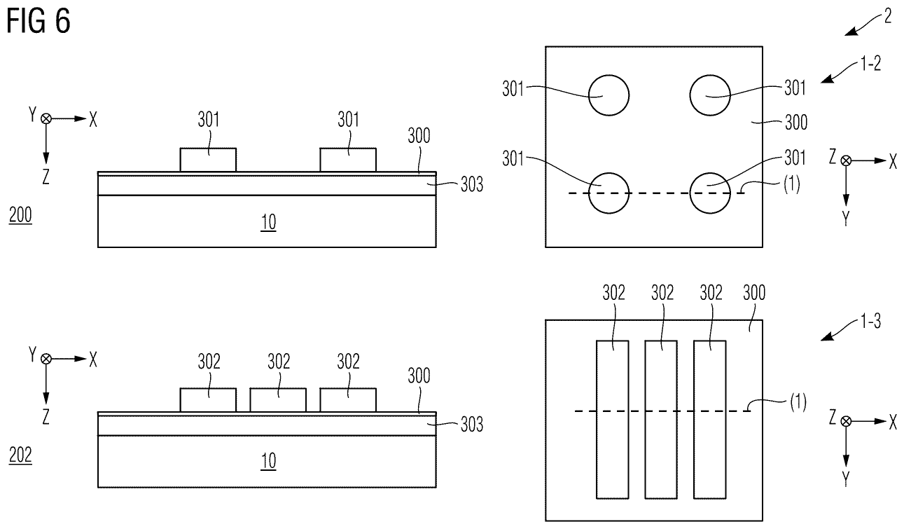

FIGS. 6-19 illustrate an exemplary embodiment of the power semiconductor production method 2.

In a processing stage 200, cf. FIG. 6, to produce the trench structure 14, 16, circular structures 301 are formed in the active region 1-2, and a processing stage 202, which can be carried out simultaneously with a processing stage 200, line structures 302 are formed in the edge termination region 1-3. For example, the circular structures 301 and line structures 302 are based on a resist layer formed on top of an oxide layer 300 above a carbon layer 303 above the semiconductor body 10. The two drawings on the right side of FIG. 6 show horizontal cross-sections and the two drawings on the left side of FIG. 6 show vertical cross-sections at the dashed lines (1).

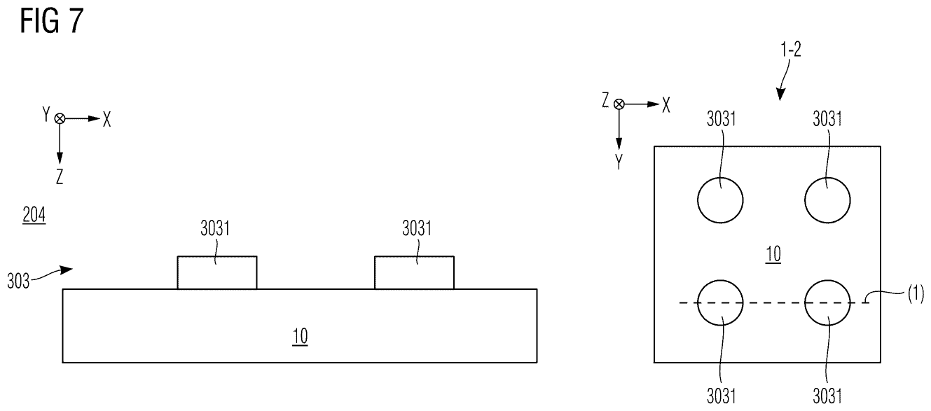

In a subsequent processing stage 204, cf. FIG. 7, which is only illustrated for the active region 1-2 but which may likewise be implemented in the edge termination region 1-3, structures 301 and 302 and the oxide layer 300 are removed, e.g., based on an etch processing step and a strip processing step, so as to form corresponding structures 3031 in the (former) carbon layer 303.

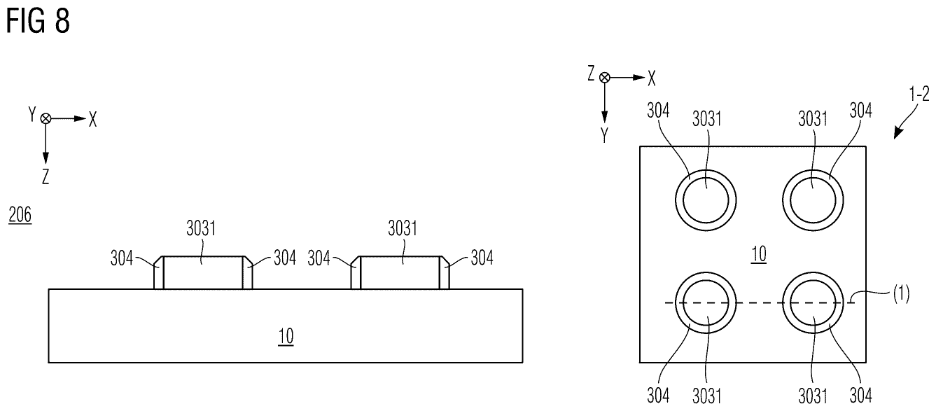

In a subsequent processing stage 206, cf. FIG. 8, which is only illustrated for the active region 1-2 but which may likewise be implemented in the edge termination region 1-3, spacers 304 are formed adjacent to the corresponding structures 3031, e.g., based on a deposition processing step and an etch processing step.

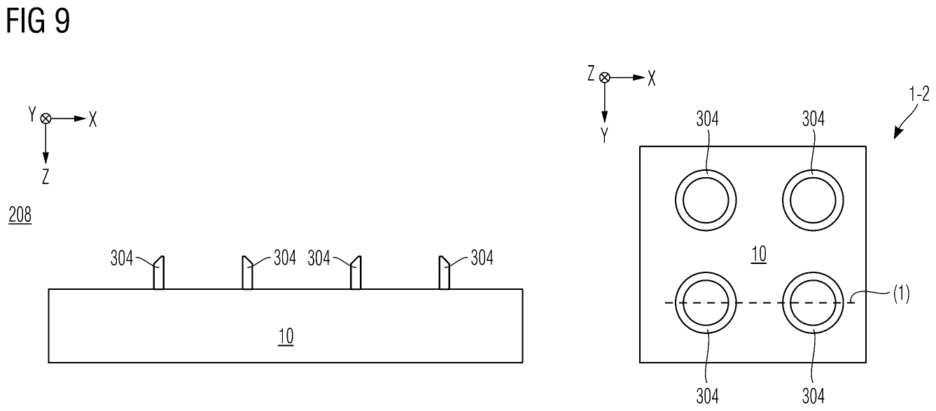

After a subsequent processing stage 208, cf. FIG. 9, which is again only illustrated for the active region 1-2 but which may likewise be implemented in the edge termination region 1-3, spacers 304 are free-standing as structures 3031 are removed in stage 208, e.g., based on an etch processing step or a strip processing step.

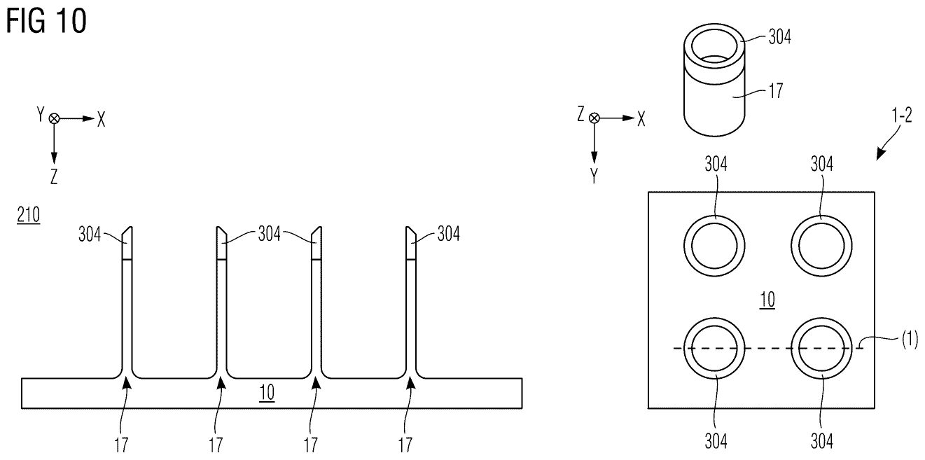

Then, in subsequent processing stage 210, cf. FIG. 10, which is again only illustrated for the active region 1-2 but which may likewise be implemented in the edge termination region 1-3, based on the spacers 304, e.g., acting as hard-mask, trenches are formed in the semiconductor body 10, e.g., based on an etch processing step. Thereby, chimney-shaped portions of the semiconductor body 10 (cf. also upper right part of FIG. 10 illustrating a perspective view) may come into being, which can be configured as the mesas 17 in subsequent processing stages.

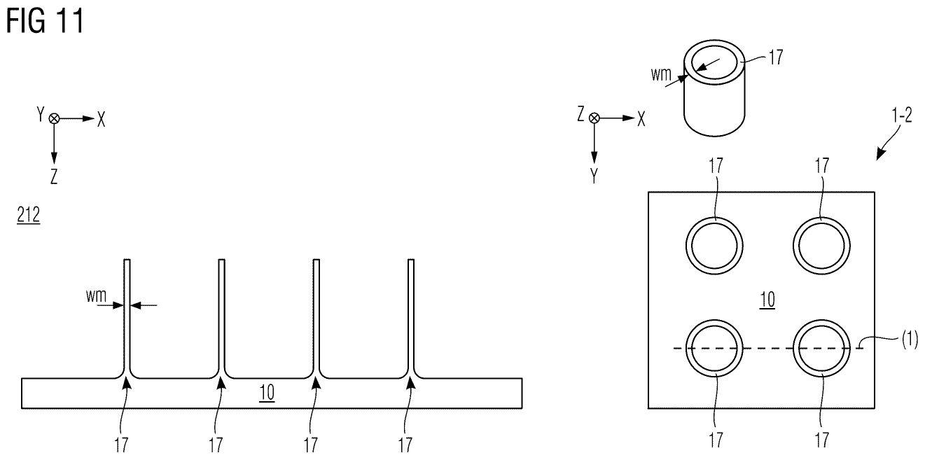

In a subsequent processing stage 212, cf. FIG. 11, which is again only illustrated for the active region 1-2 but which may likewise be implemented in the edge termination region 1-3, the spacers 304 are removed. Also, the widths wm of the mesas 17 may be reduced, e.g., by one or more isotropic etch processing steps.

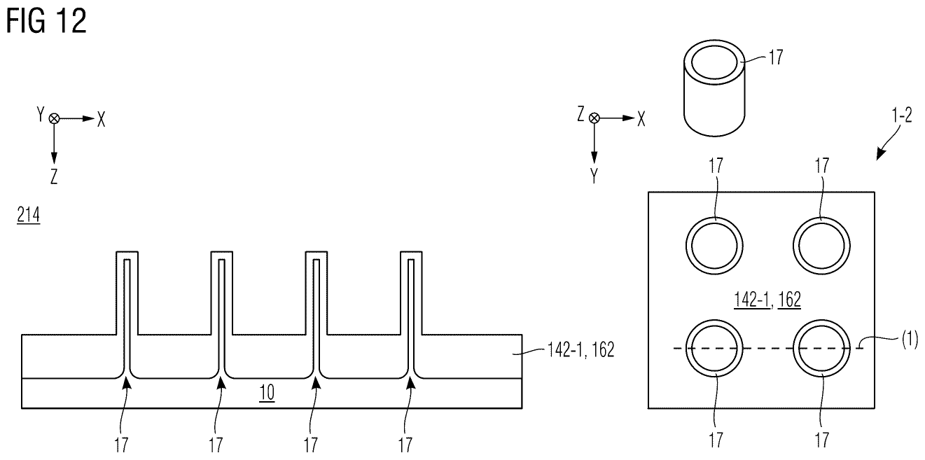

In a subsequent processing stage 214, cf. FIG. 12, which is again only illustrated for the active region 1-2 but which may likewise be implemented in the edge termination region 1-3, the lower part of the control trench insulator 142-1 and the source trench insulator 162 is formed, e.g., based on a deposition and one or more etch back processing steps, e.g., a high-density plasma chemical vapor deposition processing step, e.g., dry and/or wet etch processing steps. For example, processing stage 214 is carried out such that the insulator structure exhibits, at a bottom of the respective trench 14/16, a thickness along the vertical direction Z greater than 150% of a thickness along the first lateral direction X of the insulator structure laterally adjacent to the mesa 17. For example, depending on the magnitude of the control voltage, the thickness along the first lateral direction X of the insulator structure laterally adjacent to the mesa 17 may be in the range of 10 nm to 50 nm, or in the range of 50 nm to 150 nm, whereas the insulator structure at the bottom of the respective trench 14/16 may have a thickness along the vertical direction Z of 15 nm to 75 nm, or in the range of 75 nm to 300 nm.

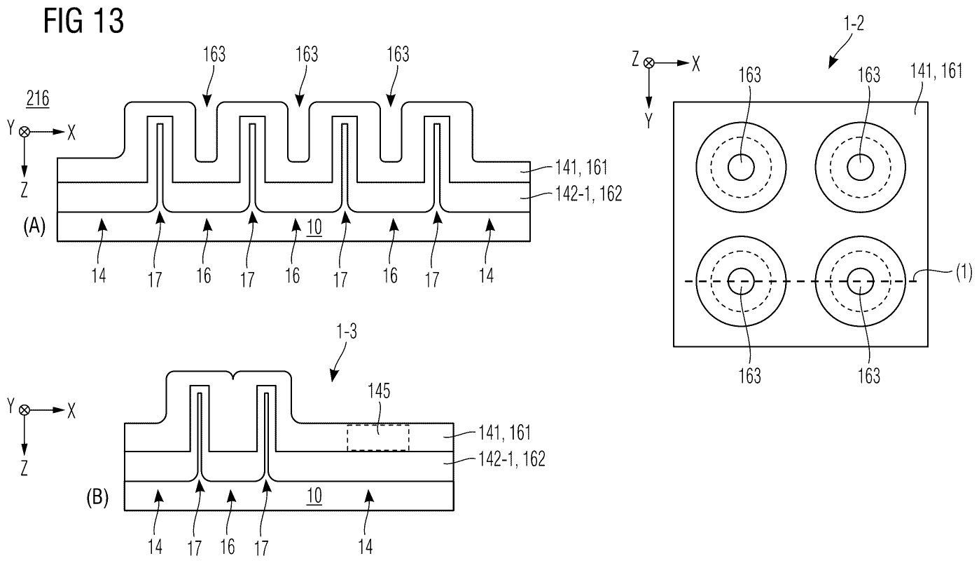

In a subsequent processing stage 216, cf. FIG. 13, which is again only illustrated for the active region 1-2 but which may likewise be implemented in the edge termination region 1-3, material for forming the control trench electrodes 141 and the source trench electrodes 161 is deposited. Depending on the amount of said material and the diameter of the chimney-shaped mesas 17, a respective void 163 may remain in the source trenches 16, cf. variant (A), or not (cf. variant (B)). Further, some of said material may be removed, e.g., in the region indicated with reference numeral 145, e.g., to adjust a total capacity of the control trench electrodes 141.

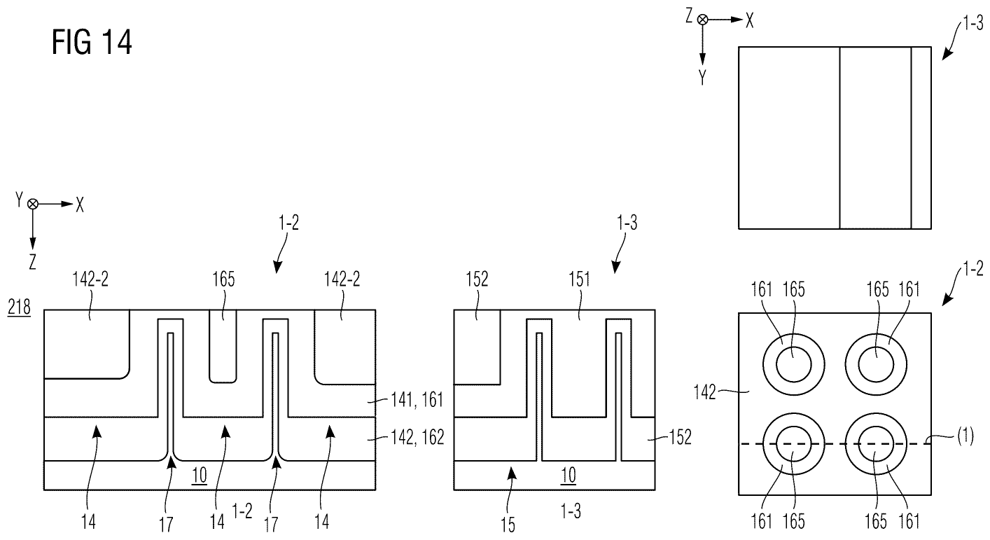

In a subsequent processing stage 218, cf. FIG. 14, the upper portion 142-2 of the control trench insulator structure is formed and said voids 163, if present, are filled with the same material 165. For example, no voids came into being in the connector trench 15, as illustrated. For example, a deposition processing step followed by a chemical-mechanical polishing, CMP, processing step may be carried out in stage 218.

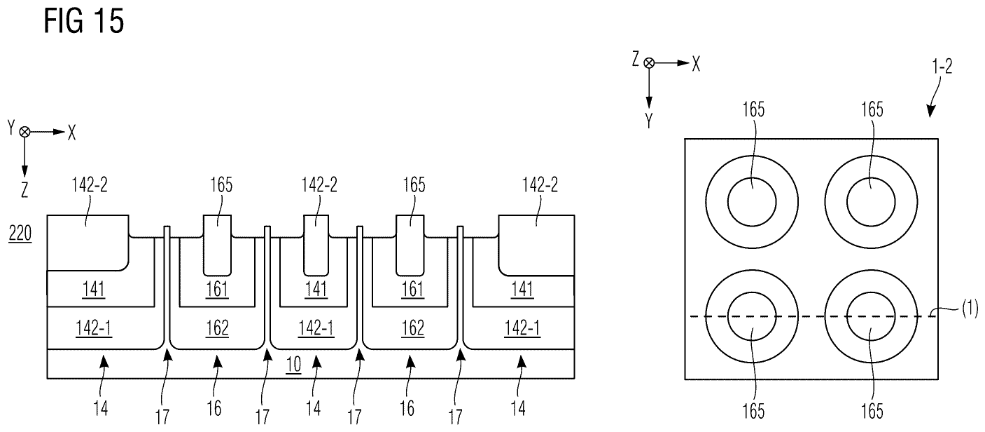

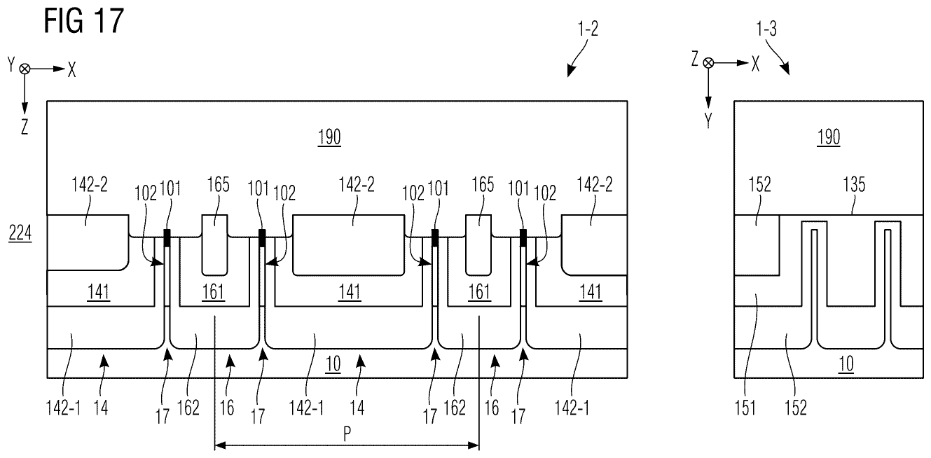

In a subsequent processing stage 220, cf. FIG. 15, which is again only illustrated for the active region 1-2, a material removal step is carried out to separate the source trench electrodes 161 and the control trench electrodes 141 from each other and to expose upper portions of the mesas 17. For example, an etch processing step is carried out recessing the electrode material of the source trench electrodes 161 and the control trench electrodes 141, and followed, for example, by an etch processing step removing parts of the isolation material of the trench insulator structure with the lower part 142-1 and the upper part 142-2. Further, not-illustrated, in the edge termination region 1-3, a control terminal runner 135 (cf. FIG. 17) for the electrical connection of the control trench electrodes can be formed, e.g., by protecting this area with a lithographic mask.

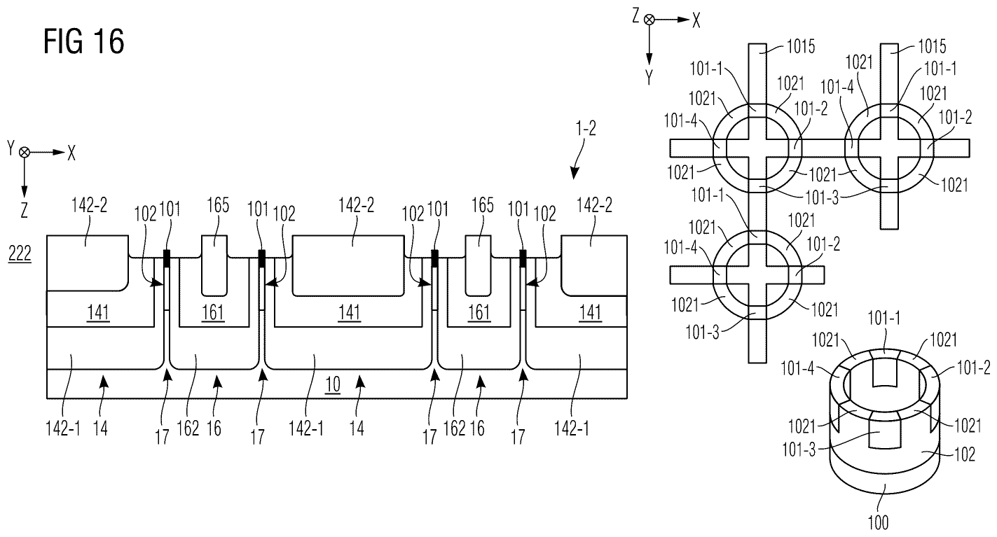

In a subsequent processing stage 222, cf. FIG. 16, which is again only illustrated for the active region 1-2, the semiconductor source regions 101 and the semiconductor body region 102 are formed in the mesas 17. In this context, it is also referred to the description above related to the device, in particular with regards to FIGS. 3(A), 3(B), 3(C), 4 and 5; this description analogously applies here. For example, the semiconductor source regions 101 and the semiconductor body region 102 are formed based on implantation processing steps and preceding lithography processing steps, e.g., so as to form said four semiconductor source subregions 101-1, 101-2, 101-3 and 101-4, as illustrated in the upper right part of FIG. 16.

In a subsequent processing stage 224, cf. FIG. 17, the insulation layer 190 is formed both in the active region 1-2 and in the edge termination region 1-3.

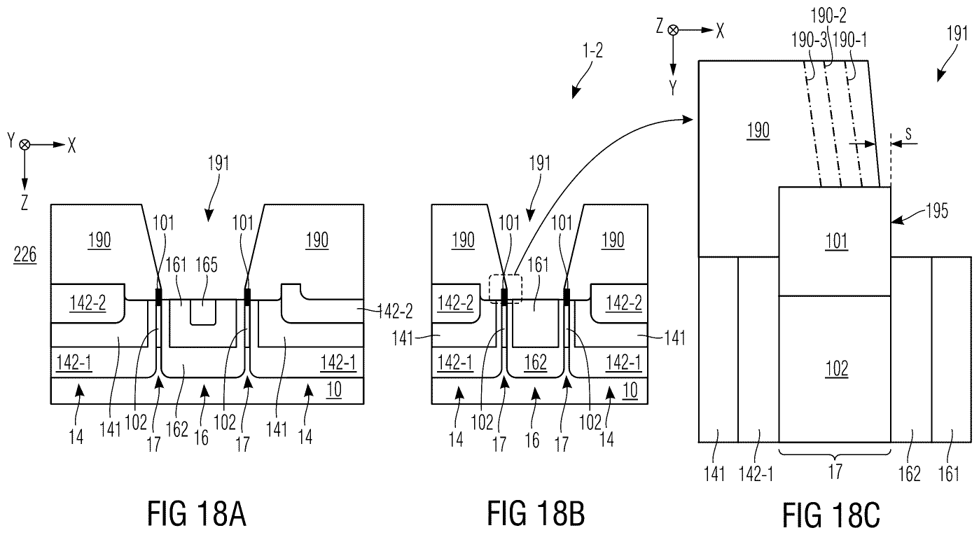

In a subsequent processing stage 226, cf. FIG. 18, which is only illustrated for the active region 1-2 but which may likewise be implemented in the edge termination region 1-3, contact trenches 191 for the first contact plugs 111 and, optionally, the second contact plugs 131 (not illustrated) are formed. Part (A) in FIG. 18 illustrates the source trench electrodes 161 with a respective void filled with insulator 165, and part (B) in FIG. 18 illustrates the source trench electrodes 161 without a void. Part (C) illustrates an enlarged view of the area indicated with reference numeral 198 in part (B). For example, the contact trenches 191 are formed based on oxide etch processing step that is selective to silicon, which may allow for forming self-aligned first contact plugs 111. The contact trenches 191 expose portions of each of the source trench electrode 161 (and, if present, portions of insulator 165), the source trench insulator 162 and portions of the mesa 17.

As illustrated, cf. also FIG. 16, along the mesa 17 source region 101 (e.g., portions of each of the four semiconductor source subregions 101-1, 101-2, 101-3 and 101-4) alternate with portions 1021 connecting the body region 102. As illustrated in part (C) of FIG. 18, the size of the contact trenches 191 may vary laterally on top of mesa 17 (reference numerals 190-1, 190-2 and 190-3) and cause insulation layer 190 to be pulled back by the distance s along/against the first lateral direction X. However, the size of the contact trenches 191 between the mesas 17 is confined by the dimension of these chimney-like structures (cf. FIG. 4(A), 4(B), 4(C)). Due to the extension of contact trench 191 in direction Z beyond the top of mesa, a stable vertical contact area 195 is formed. As illustrated, cf. also FIG. 16, contact is established to source region 101 (e.g., portions of each of the four semiconductor source subregions 101-1, 101-2, 101-3 and 101-4) alternating with portions 1021 connecting the body region 102. The variation caused by process tolerances, e.g., lithography processing steps, e.g. etch processing steps, can therefore be tolerated with such a structure as the lateral flanks 190-1, 190-2 and 190-3 do not cause meaningful degradation of contact properties. The second contact trenches for contact plugs 131 (not illustrated) may be formed in a similar fashion, but no restrictions apply like for contact trenches 191.

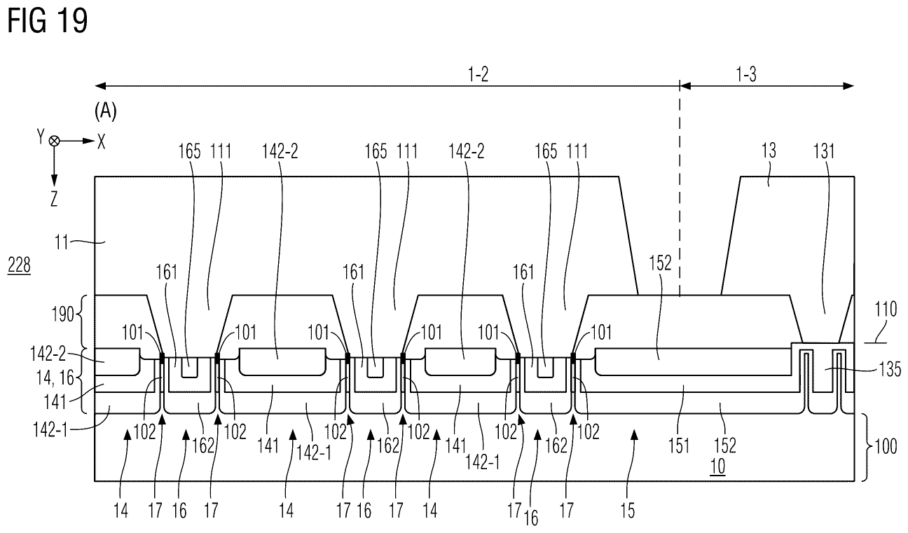

In a subsequent processing stage 228, cf. FIG. 19, the first and second contact plugs 111, 131 are formed as well as the first load terminal 11 and the control terminal 13. FIG. 19 mainly corresponds to FIG. 3(A), such that the description of FIG. 19 is referred to the above. In contrast to FIG. 3(A), the source trench electrodes 161 in FIG. 19 include said voids filled with insulator 165.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixCl-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
an active region surrounded by an edge termination region;
a semiconductor body extending in both the active region and the edge termination region and comprising, in the active region, a semiconductor drift region of a first conductivity type;
a first load terminal at a first side of the semiconductor body;
a second load terminal at a second side of the semiconductor body opposite to the first side, wherein the power semiconductor device is configured to conduct, in the active region, a forward load current between the first load terminal and the second load terminal;
in the active region, a trench structure extending along a vertical direction from the first side towards the second side,
wherein the trench structure comprises:
one or more control trenches each including a control trench electrode isolated from the first load terminal and configured to control the forward load current; and
a plurality of source trenches each including a source trench electrode electrically connected to the first load terminal;
in the active region, a plurality of mesas configured to conduct the forward load current and extending along the vertical direction from the first side towards the second side, wherein each mesa surrounds a respective one of the source trenches and is surrounded by one or more of the one or more control trenches; and
in the active region, a plurality of first contact plugs extending along the vertical direction from the first load terminal towards the first side, wherein each first contact plug is associated with one of the source trenches and one of the mesas surrounding the source trench and is configured to contact both the mesa and the source trench electrode of the source trench.

2. The power semiconductor device of claim 1, wherein each mesa comprises:
a semiconductor source region of the first conductivity type electrically connected to the first load terminal via the associated first contact plug; and
a semiconductor body region of a second conductivity type in contact with the semiconductor source region.

3. The power semiconductor device of claim 1, wherein each mesa has a width within a range of 50 nm to 500 nm.

4. The power semiconductor device of claim 1, wherein each of the one or more control trenches and each of the source trenches has a vertical extension within a range of 0.5 um to 3 μm.

5. The power semiconductor device of claim 1, wherein each of the source trenches has a lateral cross-sectional area smaller than the lateral cross-sectional area of the associated first contact plug.

6. The power semiconductor device of claim 1, wherein for each of the source trenches, the associated first contact plug laterally overlaps with both the entire source trench and at least partially with the mesa surrounding the source trench.

7. The power semiconductor device of claim 1, wherein each of the first contact plugs has a monolithic structure.

8. The power semiconductor device of claim 1, wherein the lateral cross-sectional area of each of the first contact plugs decreases along the vertical direction by at least 10% of a maximal lateral cross-sectional area of the respective first contact plug.

9. The power semiconductor device of claim 1, wherein each of the mesas has a circular lateral cross-sectional area, a rectangular lateral cross-sectional area with rounded corners, or a rectangular lateral cross-sectional area.

10. The power semiconductor device of claim 1, wherein in each of the mesas, the semiconductor source region has an even number of spatially distributed semiconductor source subregions.

11. The power semiconductor device of claim 1, wherein in each of the mesas, the semiconductor body region is arranged at least partially below the semiconductor source region.

12. The power semiconductor device of claim 1, wherein in each of the mesas:
the semiconductor source region has an even number of spatially distributed semiconductor source subregions;
the semiconductor body region is arranged at least partially below the semiconductor source region; and
portions of the semiconductor body region extend between the spatially distributed semiconductor source subregions to electrically contact the associated first contact plug.

13. The power semiconductor device of claim 1, wherein in the active region, the control trench electrode of the one or more control trenches forms a monolithic electrode structure.

14. The power semiconductor device of claim 1, further comprising:
at the first side of the semiconductor body, a control terminal electrically connected with the control trench electrode of the one or more control trenches,
wherein a contact between the control terminal and the control trench electrode of the one or more control trenches is established only in the edge termination region.

15. The power semiconductor device of claim 14, further comprising:
a connector trench extending into the edge termination region and the active region, the connector trench comprising a connector trench electrode,
wherein the connector trench electrode:
is arranged, in the edge termination region, in contact with a second contact plug electrically connected to the control terminal; and
extends towards an adjacent one of the mesas in the active region.

16. The power semiconductor device of claim 1, wherein the trench structure has a pattern, in the active region, according to which each source trench is surrounded by one or more of control trenches.

17. The power semiconductor device of claim 1, wherein the active region is devoid of any electrically conducting structure above the first side of the semiconductor body that is electrically connected to one or more control trench electrodes.

18. The power semiconductor device of claim 1, wherein:
each of the one or more control trenches comprises a control trench insulator structure insulating the respective control trench electrode from the semiconductor body;
the control trench insulator structure has, at a bottom of the respective control trench, a thickness along the vertical direction greater than 150% of a thickness along a lateral direction of the control trench insulator laterally adjacent to the mesa; and/or
each of the source trenches comprises a source trench insulator insulating the respective source trench electrode from the semiconductor body, the source trench insulator having, at a bottom of the respective source trench, a thickness along the vertical direction greater than 150% of a thickness along a lateral direction of the source trench insulator laterally adjacent to the mesa.

19. The power semiconductor device of claim 1, wherein each control trench electrode has, in a vertical cross-section, a U-shape.

20. A method of producing a power semiconductor device, the method comprising:
forming an active region surrounded by an edge termination region;
forming a semiconductor body extending in both the active region and the edge termination region and comprising, in the active region, a semiconductor drift region of a first conductivity type;
forming a first load terminal at a first side of the semiconductor body;
forming a second load terminal at a second side of the semiconductor body opposite to the first side, wherein the power semiconductor device is configured to conduct, in the active region, a forward load current between the first load terminal and the second load terminal;
in the active region, forming a trench structure extending along a vertical direction from the first side towards the second side, wherein the trench structure comprises: one or more control trenches each including a control trench electrode isolated from the first load terminal and configured to control the forward load current; and a plurality of source trenches each including a source trench electrode electrically connected to the first load terminal;
in the active region, forming a plurality of mesas configured to conduct the forward load current and extending along the vertical direction from the first side towards the second side, wherein each mesa surrounds one of the source trenches and is surrounded by one or more of the one or more control trenches; and
in the active region, forming a plurality of first contact plugs extending along the vertical direction from the first load terminal towards the first side, wherein each first contact plug is associated with one of the source trenches and one of the mesas surrounding the source trench and is configured to contact both the mesa and the source trench electrode of the source trench.

21. The method of claim 20, wherein each control trench electrode and each source trench electrode is electrically contacted based on a joint etch processing step.

22. The method of claim 20, wherein forming the first contact plugs occurs such that the first contact plugs are self-aligned.
